(19) United States
(12) Patent Application Publication
(10) Pub. No.: US 2011/0102752 A1
(43) Pub. Date: May 5, 2011

(54) POSITIONING STAND AND ELECTRONIC APPARATUS HAVING THE SAME

(75) Inventors: CHENG-HSIN CHEN, Taipei (TW); Lin-Jun Suen, Taipei (TW); Yu-Shiang Chang, Taipei (TW)

(73) Assignee: INVENTEC CORPORATION, Taipei (TW)

(21) Appl. No.: 12/727,364

(22) Filed: Mar. 19, 2010

(30) Foreign Application Priority Data
Oct. 30, 2009 (TW) 098136866

(51) Int. Cl. G03B 21/14; F16M 13/00; H05K 5/00

(52) U.S. Cl. 353/119; 248/346.06; 361/679.01

(57) ABSTRACT

A positioning stand is provided, which comprises: a support; a positioning base, engaged to the support and having an accommodating base at a lateral side thereof; a locking rod, disposed passing through the positioning base and the support and having a locking part in contact with the accommodating base; a knob, connected to an end portion of the locking rod protruding from the support; and a resilient element, disposed between the support and the knob; wherein the knob is capable of changing a position of the locking part through compression of the resilient element and a rotation motion and the support compresses the resilient element to adjust an angle of the support, and the positioning stand is combined with an electronic apparatus, so as to adjust a tilting angle of the electronic apparatus, thus enhancing a cooling effect of the electronic apparatus and increasing comforts of using the electronic apparatus.

### BACKGROUND OF THE INVENTION

1. Field of Invention

The present invention relates to a stand, and more particularly to a positioning stand having multiple positioning angles to adjust a tilting angle of an electronic apparatus and an electronic apparatus having the same.

2. Related Art

Portable electronic apparatuses, such as notebook computers and mobile phones, have been widely used in people's daily life with the improvement of technology. Taking the notebook computer as an example, as shown in FIG. 1, currently a notebook computer 1 usually lies flat on a desktop 10 during use. The notebook computer 1 basically includes a screen 11 and a main unit body 12. When the notebook computer 1 lies flat on the desktop 10, the main unit body 12 of the notebook computer 1 directly contacts with the desktop 10 and also a keyboard 13 of the notebook computer 1 is directly disposed on the main unit body 12, so that the keyboard 13 is also in a flat state without any tilting angle, therefore, it is very inconvenient for a user to operate the keyboard 13.

In addition, in the conventional notebook computer, as the main unit body is directly placed on the desktop, only lateral sides can be used as cooling space. As a lot of expansion connection interfaces, such as an RGB terminal interface, a USB interface, a memory card reading interface, and a network interface, have to be disposed on the lateral sides, available cooling space becomes smaller. In spite of assistance with a cooling fan, an overheating problem usually occurs due to different space configurations and use environments.

For the above problems, currently additional support frame fittings can provide a better operation state for a user, which keeps a tilting angle for the main unit body of the notebook computer. Additional fans are usually disposed on the support fittings to enhance the cooling effect of the main unit body. However, the additional fittings are separated from the notebook computer and occupy a considerable volume in both use and accommodated states. Thus, it is inconvenient to carry the additional fittings and the notebook computer together, so that the practicability of the cooling fittings is decreased and limited.

In order to solve the above problems, in the prior art, for example, an elevating support is disclosed in ROC Utility Patent Publication M347606. In use, the elevating support can be used to elevating an end of the notebook computer, so that the notebook computer tilts with an angle. This technique adjusts an angle of the notebook computer, however, as the elevating support is formed of a plurality of connecting rods, the number of elements is large and angle positioning is very inconvenient. Also, the elevating support is unable to be accommodated when it is not used, resulting in that a tail portion of the notebook computer protrudes from the elevating support, which increases the inconvenience in space.

### SUMMARY OF THE INVENTION

The present invention is directed to a positioning stand and an electronic apparatus having the same, which have a multi-angle adjustment mechanism to change a tilting angle of an electronic apparatus, so that a user can make multi-angle adjustment when the user uses the electronic apparatus and thus comfort of operation by the user is improved.

The present invention is directed to a positioning stand and an electronic apparatus having the same, which use a multi-angle adjustment mechanism in combination with a current electronic apparatus having a projection function to adjust a projection angle dynamically as desired, so that the user can freely adjust a projection view angle to an optimal visual situation.

The present invention is directed to a positioning stand and an electronic apparatus having the same, which utilizes a multi-angle adjustment mechanism to change a tilting angle of an electronic apparatus, so as to increase air circulation, thus enhancing a cooling effect of the electronic apparatus.

In an embodiment, the present invention provides a positioning stand, which includes a positioning base, a support, a locking rod, a knob, and a resilient element. The positioning base has a gear type structure at a lateral side and an accommodating base at the other lateral side. The accommodating base has a first through hole passing through the positioning base. The support is engaged to the gear type structure, and has a second through hole corresponding to the first through hole. The locking rod protrudes from the support through the first through hole and the second through hole, and has a locking part in contact with the accommodating base. The knob is connected to an end portion of the locking rod protruding from the support. The resilient element is disposed between the support and the knob, so that the knob changes a position of the locking part through compression of the resilient element and a rotation motion and the support compresses the resilient element to adjust an angle of the support.

In another embodiment, the present invention further provides an electronic apparatus having positioning stands, which includes an electronic apparatus and a pair of positioning stands. The electronic apparatus has a slot on each sidewall at two sides respectively. The pair of positioning stands is connected on the two sidewalls of the electronic apparatus respectively. Each positioning stand includes a positioning base, a support, a locking rod, a knob, and a resilient element. The positioning base has a gear type structure on a lateral side and an accommodating base on the other lateral side. The accommodating base is accommodated in the slot on a corresponding sidewall, and has a first through hole passing through the positioning base. The support is engaged to the gear type structure, and has a second through hole corresponding to the first through hole. The locking rod protrudes from the support through the first through hole and the second through hole, and has a locking part. The knob is connected on an end portion of the locking rod protruding from the support. The resilient element is disposed between the support and the knob, so that the knob drives the locking part to select to be in contact with the accommodating base or in contact with the corresponding sidewall through compression of the resilient element and a rotation motion, and the support compresses the resilient element to adjust an angle of the support.

In another embodiment, the present invention further provides an electronic apparatus having positioning stands, which includes an electronic apparatus, a projection unit, and a pair of positioning stands. The electronic apparatus has a slot on each sidewall at two sides respectively. The projection unit is disposed inside the electronic apparatus, for projecting an image. The pair of positioning stands is connected on the two sidewalls of the electronic apparatus respectively, for adjusting a tilting angle of the electronic apparatus, so as to adjust a projection angle of the projection unit. Each positioning stand includes a positioning base, a support, a locking rod, a knob, and a resilient element. The positioning base has a gear type structure on a lateral side and an accommodating base on the other lateral side. The accommodating base is accommodated in the slot on the corresponding sidewall, and has a first through hole passing through the positioning base. The support is engaged to the gear type structure, and has a second through hole corresponding to the first through hole. The locking rod protrudes from the support through the first through hole and the second through hole, and has a locking part. The knob is connected to an end portion of the locking rod protruding from the support. The resilient element is disposed between the support and the knob, so that the knob drives the locking part to select to be in contact with the accommodating base or in contact with the corresponding sidewall through compression of the resilient element and a rotation motion, and the support compresses the resilient element to adjust an angle of the support.

### BRIEF DESCRIPTION OF THE DRAWINGS

The present invention will become more fully understood from the detailed description given herein below for illustration only, and thus are not limitative of the present invention, and wherein:

FIG. 1 is a schematic view of a use state of a conventional electronic apparatus;

FIG. 2A is a 3 dimensional schematic exploded view of a positioning stand according to an embodiment of the present invention;

FIGS. 2B and 2C are schematic sectional views of a positioning base and a support according to the present invention respectively;

FIG. 3A is a schematic exploded view of combination of a positioning stand and an electronic apparatus according to the present invention;

FIGS. 3B to 3D are schematic views of motions of a knob of an electronic apparatus according to an embodiment of the present invention;

FIG. 3E is a schematic view of combination of a positioning stand and an electronic apparatus;

FIG. 4 is a schematic view of internal of an electronic apparatus having positioning stands according to the present invention;

FIGS. 5A and 5B are schematic views of angle adjustment motions of a support according to the present invention;

FIG. 5C is a schematic view illustrating accommodation of a positioning stand according to the present invention;

FIG. 6 is a schematic view of an electronic apparatus according to another embodiment of the present invention; and

FIGS. 7A and 7B are schematic views of a positioning stand according to another embodiment of the present invention.

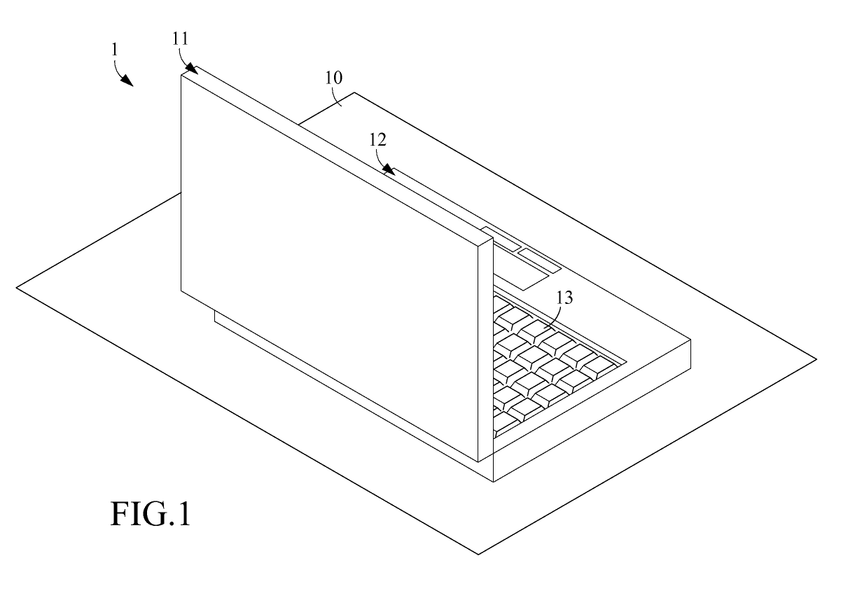

### DETAILED DESCRIPTION OF THE INVENTION

In order to provide the examiner with further awareness and understanding of the features, objectives, and functions of the present invention, the related detailed structures and design conceptions and reasons of the apparatus of the present invention are illustrated below, so that the examiner can understand the characteristics of the present invention. The detailed illustration is as follows.

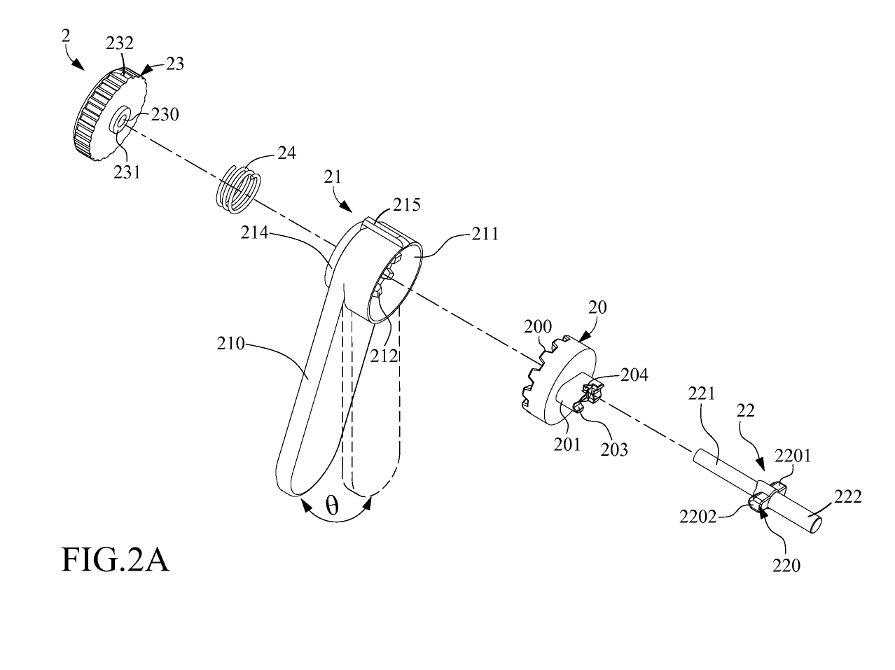

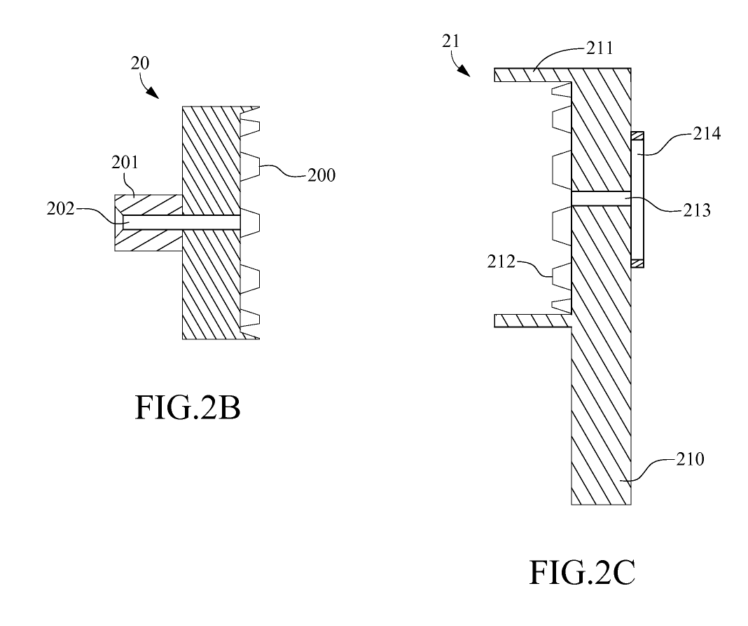

Referring to FIGS. 2A to 2C, FIG. 2A is a 3D schematic exploded view of a positioning stand according to an embodiment of the present invention. FIGS. 2B and 2C are schematic sectional views of a positioning base and a support according to the present invention respectively. The positioning stand 2 includes a positioning base 20, a support 21, a locking rod 22, a knob 23, and a resilient element 24. The positioning base 20 has a gear type structure 200 on a lateral side thereof and an accommodating base 201 on the other lateral side. The accommodating base 201 has a first through hole 202 passing through the positioning base 20. The accommodating base 201 has a pair of grooves 203 and 204 intersecting each other. In this embodiment, an intersection angle is 90 degrees, but the present invention is not limited thereto. The support 21, engaged to the gear type structure 200, is extended with a foot part 210. In this embodiment, a cover 211 is provided at a side of the support 21 corresponding to the positioning base 20, and has teeth 212 that can be engaged to the gear type structure 200. The cover 211 is not an essential means, which can be disposed or removed by the user according to the demands. The support 21 has a second through hole 213 corresponding to the first through hole 202.

The locking rod 22 protrudes from the support 21 through the first through hole 202 and the second through hole 213. The locking rod 22 has a locking part 220 and a first rod 221. The first rod 221 penetrates the positioning base 20 and the support 21 and protrudes from the support 21, so that the locking part 220 is in contact with the accommodating base 201. In this embodiment, the locking part 220 is a pair of convex bodies 2201 and 2202, which contacts with the groove 203 when the first rod 221 penetrates the positioning base 20 and the support 21 through the first through hole 202 and the second through hole 213. The knob 23 is connected to an end portion of the locking rod 22 protruding from the support 21 through a through hole 230. Connection between the knob 23 and the locking rod 22 is fixed, so that the knob 23 can drive the locking rod 23 to rotate synchronously. The resilient element 24 is disposed between the support 21 and the knob 23. In this embodiment, the resilient element 24 is provided for the locking rod 22 to pass through so that the resilient element 24 is disposed between the support 21 and the knob 23. The knob 23 further has a convex ring 231. When the convex ring 231 is combined with the resilient element 24, an outer edge of the convex ring 231 is in contact with an inner wall at an end of the resilient element 24, so as to provide an end for positioning the resilient element 24. The support 21 further has a groove 214 to provide the other end for accommodating the resilient element 24.

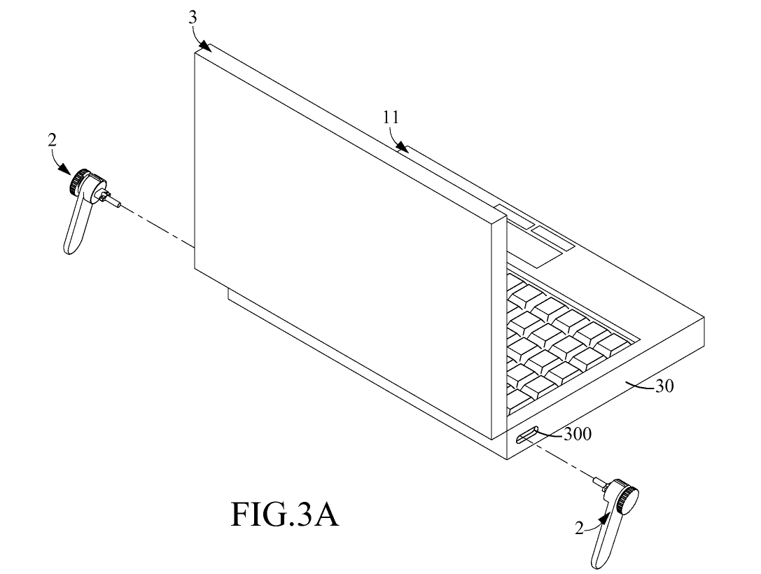

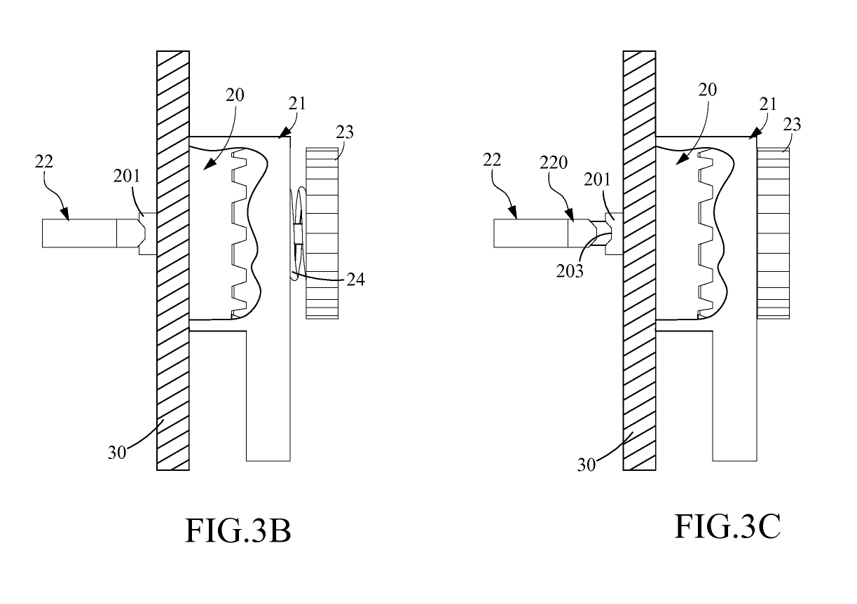

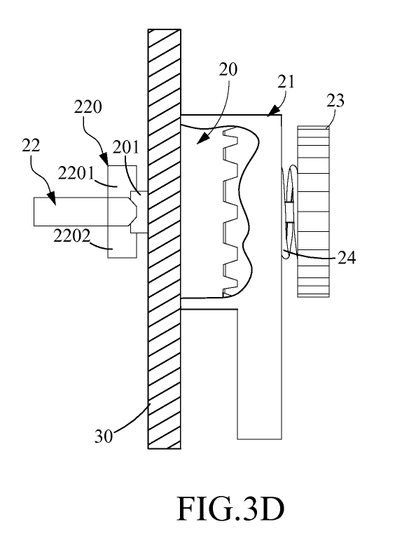

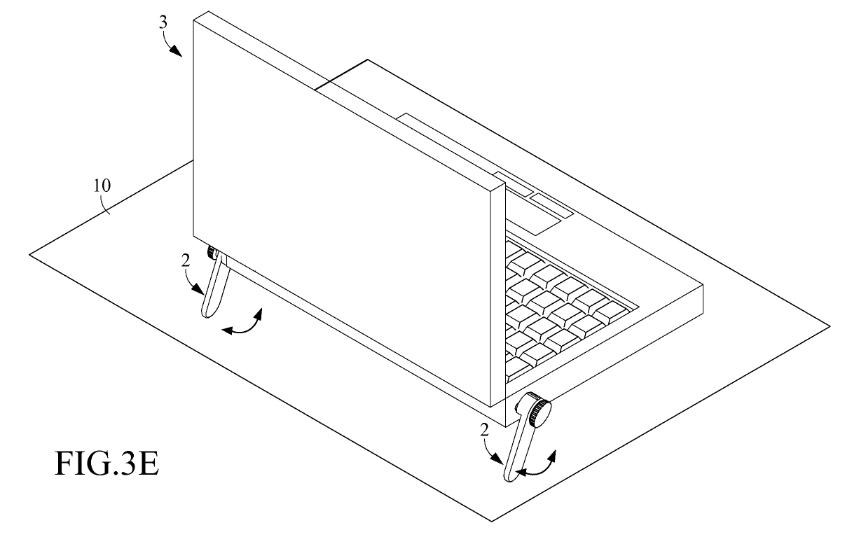

FIG. 3A is a schematic view of combination of a positioning stand and an electronic apparatus according to the present invention. In FIG. 3A, two sidewalls 30 (only one sidewall is shown in FIG. 3A) of the electronic apparatus 3 each have a slot 300. The electronic apparatus 3 in this embodiment is a notebook computer, but the present invention is not limited thereto. A positioning stand 2 can be accommodated in each slot 300. FIGS. 3B to 3D show schematic views of motions of a knob of the electronic apparatus according to an embodiment. FIG. 3B shows an initial state after the positioning stand 2 is assembled. The support 21 and the positioning base 20 are engaged to each other. Two convex bodies 2201 and 2202 of the locking part 220 are in contact with the accommodating base 201. When the accommodating base 201 of the positioning base 20 is inserted in the corresponding slot, the sidewall at outside of the accommodating base 201 is in contact with the sidewall 30 of the electronic apparatus 3.

In order to fix the positioning stand 2 on the electronic apparatus 3, as shown in FIG. 3C, the user can compress the knob 23. As the positioning stand 2 uses the sidewall 30 of the electronic apparatus 3 as a constraint, the knob 23 can compress the resilient element 24 so that the locking part 220 disengages from the groove 203 of the accommodating base 201. At this time, the user can rotate the knob 23 by a certain angle, in this embodiment, 90 degrees. Subsequently, the force is released, so that the resilience of the resilient element 24 works on the knob 23 and the locking part 220 is brought back to be in contact with the groove 204 of the accommodating base 201 (as shown in FIG. 2A), so as to form a state as shown in FIG. 3D. At this time, as the locking part 220 rotates with an angle, the convex bodies 2201 and 2202 of the locking part 220 are blocked by the sidewall 30 of the electronic apparatus so that the positioning stand 2 cannot depart from the electronic apparatus 3. In order to facilitate the user to rotate the knob so that the locking part can correspond to the groove 203 or 204 accurately, as shown in FIG. 2A, an alignment mark structure or an alignment mark can be disposed on the knob 23 and the support 21. In this embodiment, alignment structures 232 and 215 are used to assist the user to recognize rotation positions.

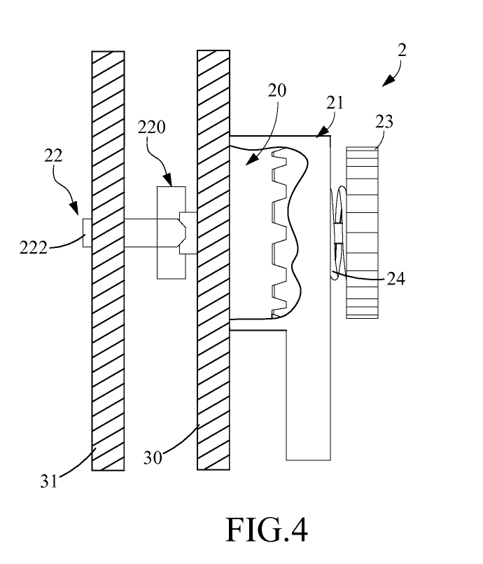

As shown in FIG. 3E, after the motion in FIG. 3D, the positioning stand 2 can be disposed on the electronic apparatus 3 without departing from the electronic apparatus 3, so that the electronic apparatus 3 disposed with the positioning stands 2 is placed on the desktop 10. Additionally, the positioning stands can be disassembled by similarly compressing the knob and rotating in an opposite direction, the description of which is omitted here. FIG. 4 is a schematic view of internal of an electronic apparatus having positioning stands according to the present invention. The electronic apparatus further has a strengthened structure 31 inside. The locking rod 22 of the positioning stand is further extended with a convex rod 222 inside the electronic apparatus. The convex rod 222 is in contact with the strengthened structure 31. The sidewall 30 of the electronic apparatus and the strengthened structure 31 are utilized to support the positioning stand 2 at the same time, so as to disperse the force on the positioning stand 2 and increase stability of the positioning stands.

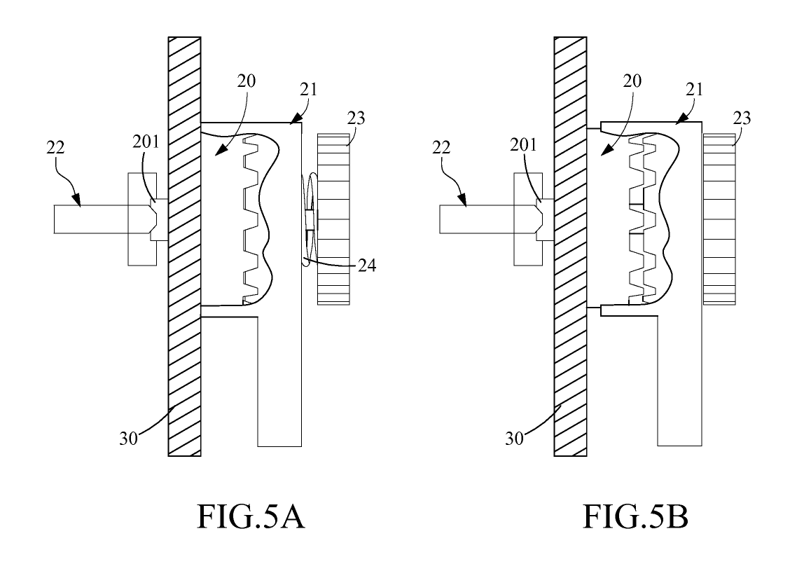

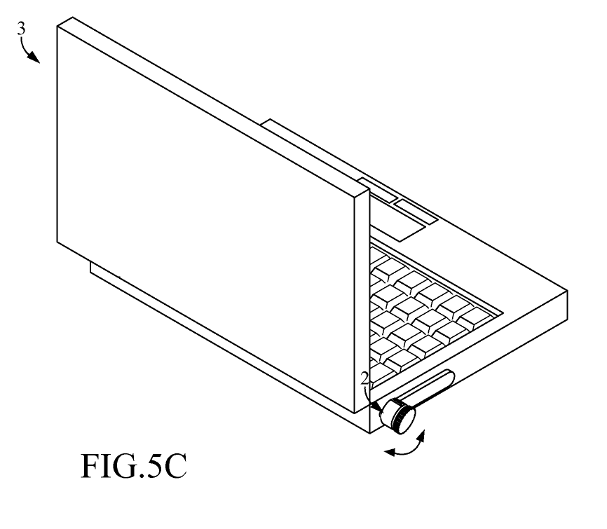

FIGS. 5A and 5B are schematic views of angle adjustment motions of a support according to the present invention. FIG. 5A shows a state in which the positioning stand is disposed on the electronic apparatus. At this time, if a tilting angle of the electronic apparatus needs to be adjusted, the user can apply an outward force on the support, so that the support 21 is released from the engagement state with the positioning base 20, as shown in FIG. 5B. At this time, as the support 21 is disengaged from the positioning base 20, the support 21 compresses the resilient element, so that resilience is accumulated at the resilient element 24. When the support 21 is disengaged from the positioning base 20, the user can rotate the support 21 to adjust the support 21 to a specific angle, which is between 0 degree and 180 degrees in this embodiment, so as to change the tilting angle of the electronic apparatus. Additionally, FIG. 5C is a schematic view illustrating accommodation of the positioning stand according to the present invention. If the user does not use the positioning stand, the operation in FIG. 5B can also be performed, so that the positioning stand 2 is accommodated to a direction consistent with a side of the electronic apparatus 3, such that the electronic apparatus 3 is accommodated more easily and the occupied space is decreased to the minimum.

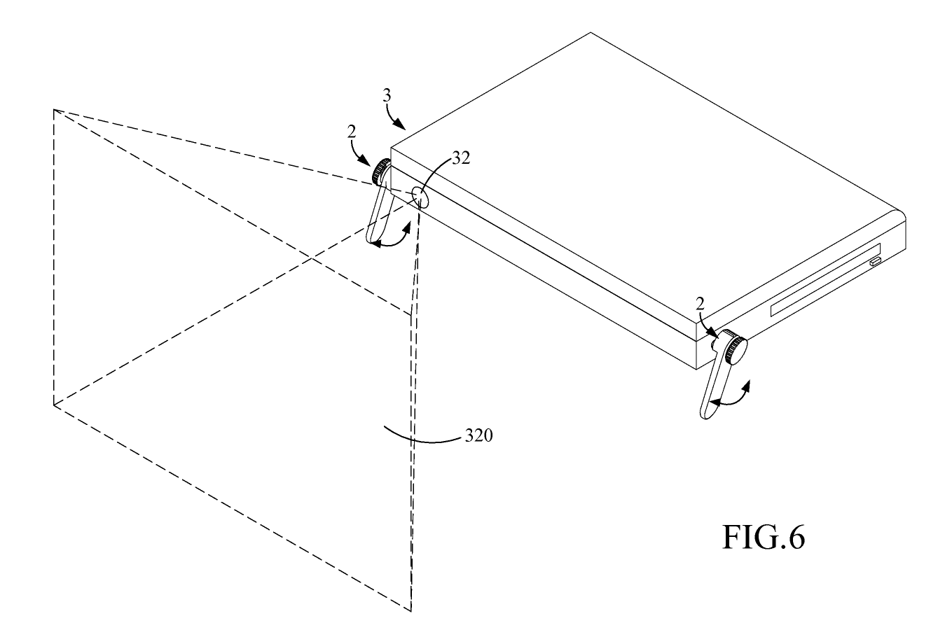

FIG. 6 is a schematic view of an electronic apparatus according to another embodiment of the present invention. In this embodiment, the electronic apparatus 3 further has a projection unit 32 for projecting an image area 320. An image can be presented in the image area 320. In order to adjust an angle of projecting the image area 320, the positioning stand 2 of the present invention is utilized and the tilting angle of the electronic apparatus is changed by rotating the support through the operation in FIG. 5B, so as to change the projection angle of the projection unit 32. Therefore, the user can freely adjust a projection view angle to an optimal visual situation. Although in this embodiment the notebook computer is taken as an example for the electronic apparatus, in other embodiments, an electronic apparatus such as a mobile phone or personal digital assistance (PDA) can also be combined with the projection unit, and a projection angle thereof can be adjusted in combination with the positioning stand according to the present invention.

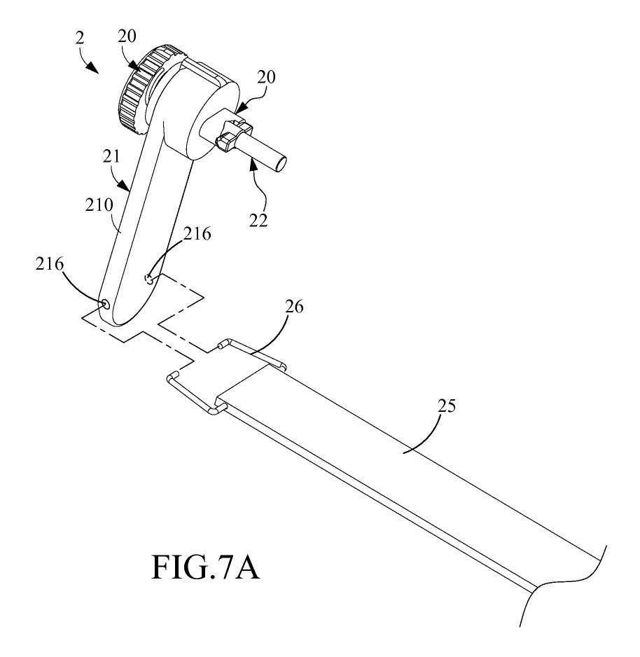

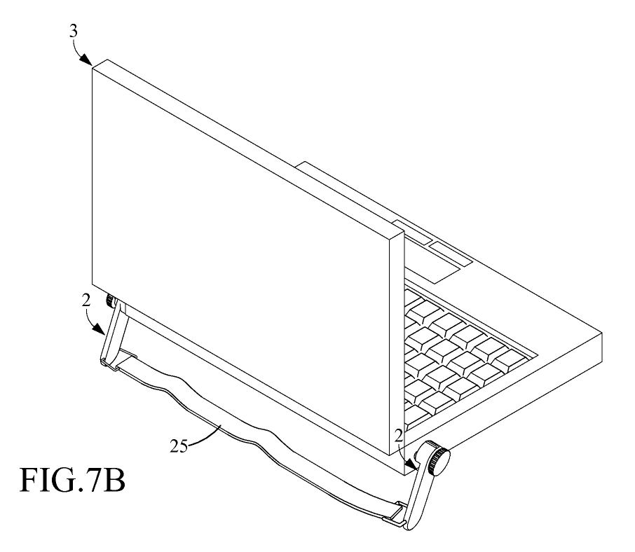

FIGS. 7A and 7B are schematic views of a positioning stand according to another embodiment of the present invention. In this embodiment, a flexible belt 25 can be further connected to end portions of positioning stands 2 disposed at two sides of the electronic apparatus 3. A pair of holes 216 is opened at an end of a foot part 210 of the support 21. An end of the flexible belt 25 has a buckle 26, and two ends of the buckle 26 can be inserted in the corresponding holes 216, so that the buckle 26 can be fixed on the foot part 210 to form a state as shown in FIG. 7B. Through the configuration of the flexible belt 25, the user can carry the electronic apparatus 3 with the flexible belt 25, thus providing a further implementation of carrying the electronic apparatus 3.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A positioning stand, comprising:
a positioning base, having a gear type structure at a lateral side thereof and an accommodating base at the other lateral side, wherein the accommodating base has a first through hole passing through the positioning base;
a support, engaged to the gear type structure and having a second through hole corresponding to the first through hole;
a locking rod, protruding from the support through the first through hole and the second through hole, and having a locking part in contact with the accommodating base;
a knob, connected to an end portion of the locking rod protruding from the support; and
a resilient element, disposed between the support and the knob, so that the knob changes a position of the locking part through compression of the resilient element and a rotation motion and the support compresses the resilient element to adjust an angle of the support.

2. The positioning stand according to claim 1, wherein the accommodating base has a pair of intersecting grooves.

3. The positioning stand according to claim 1, wherein the locking part is a pair of convex bodies connected on two sides of the locking rod, the pair of convex bodies selects to be in contact with one groove through the rotation motion provided by the knob.

4. An electronic apparatus having positioning stands, comprising:
an electronic apparatus, having a slot on each sidewall at two sides respectively;
a pair of positioning stands, connected to the two sidewalls of the electronic apparatus respectively, wherein each positioning stand comprises:
a positioning base, having a gear type structure on a lateral side thereof and an accommodating base on the other lateral side, wherein the accommodating base is accommodated inside the slot on the corresponding sidewall, and has a first through hole passing through the positioning base;
a support, engaged to the gear type structure and having a second through hole corresponding to the first through hole;
a locking rod, protruding from the support through the first through hole and the second through hole, and having a locking part;
a knob, connected to an end portion of the locking rod protruding from the support; and
a resilient element, disposed between the support and the knob, so that the knob drives the locking part to select to be in contact with the accommodating base or in contact with the corresponding sidewall through compression of the resilient element and a rotation motion and the support compresses the resilient element to adjust an angle of the support.

5. The electronic apparatus having positioning stands according to claim 4, wherein the accommodating base has a pair of intersecting grooves.

6. The electronic apparatus having positioning stands according to claim 4, wherein the locking part is a pair of convex bodies connected on two sides of the locking rod, and the pair of convex bodies selects to be in contact with one groove through the rotation motion.

7. The electronic apparatus having positioning stands according to claim 4, wherein a flexible belt is further connected at two ends of the pair of supports.

8. The electronic apparatus having positioning stands according to claim 7, wherein a third through hole is provided at two ends of the flexible belt respectively, a buckle is sleeved in each third through hole, and the buckle is connected to an end portion of the corresponding support.

9. The electronic apparatus having positioning stands according to claim 4, wherein an end of each locking part is further extended with a convex rod.

10. The electronic apparatus having positioning stands according to claim 9, wherein the electronic apparatus has a strengthened structure at a side of an inner wall surface corresponding to the two sidewalls respectively, so as to support the convex rod.

11. An electronic apparatus having positioning stands, comprising:
an electronic apparatus, having a slot on each sidewall at two sides respectively;
a projection unit, disposed inside the electronic apparatus, for projecting an image; and
a pair of positioning stands, connected to two sidewalls of the electronic apparatus respectively, for adjusting a tilting angle of the electronic apparatus so as to adjust a projection angle of the projection unit, wherein each positioning stand comprises:
a positioning base, having a gear type structure on a lateral side thereof and an accommodating base on the other lateral side, wherein the accommodating base is accommodated inside the slot on the corresponding sidewall, and has a first through hole passing through the positioning base;
a support, engaged to the gear type structure and having a second through hole corresponding to the first through hole;
a locking rod, protruding from the support through the first through hole and the second through hole, and having a locking part;
a knob, connected to an end portion of the locking rod protruding from the support; and
a resilient element, disposed between the support and the knob, so that the knob drives the locking part to select to be in contact with the accommodating base or in contact with the corresponding sidewall through compression of the resilient element and a rotation motion and the support compresses the resilient element to adjust an angle of the support.

12. The electronic apparatus having positioning stands according to claim 11, wherein the accommodating base has a pair of intersecting grooves.

13. The electronic apparatus having positioning stands according to claim 11, wherein the locking part is a pair of convex bodies connected on two sides of the locking rod, the pair of convex bodies select to be in contact with one groove according to the rotation motion.

14. The electronic apparatus having positioning stands according to claim 11, wherein a flexible belt is further connected at two sides of the pair of supports respectively.

15. The electronic apparatus having positioning stands according to claim 14, wherein a third through hole is provided at two ends of the flexible belt respectively, a buckle is sleeved in each third through hole, and the buckle is connected to an end portion of the corresponding support.

16. The electronic apparatus having positioning stands according to claim 11, wherein an end of each locking part is extended with a convex rod, and the electronic apparatus has a strengthened structure at a side of an inner wall surface corresponding to the two sidewalls respectively, so as to support the convex rod.
